(19) United States
(12) Patent Application Publication
(10) Pub. No.: US 2002/0190348 A1
(43) Pub. Date: Dec. 19, 2002

(54) Semiconductor device having anti-fuse structure

(75) Inventor: Masatoshi Anma, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 10/003,234

(22) Filed: Dec. 6, 2001

(30) Foreign Application Priority Data
Jun. 18, 2001 (JP) 2001-183766

(51) Int. Cl. H01L 29/00

(52) U.S. Cl. 257/530

(57) ABSTRACT

A lower interconnection connected to a short circuit or a spare circuit is formed on a substrate, and a dielectric film is formed so as to cover the lower interconnection. An opening section is formed in the dielectric film so as to extend to an upper surface of the lower interconnection. A plug is formed in the opening section. An upper interconnection is formed on the plug by way of a predetermined void and is connected to a load circuit. When the upper interconnection and the lower interconnection are subjected to antifuse connection, electromigration is induced in an aluminum interconnection on the upper interconnection, thereby interconnecting the upper interconnection and the plug.

### BACKGROUND OF THE INVENTION

1. Field of the Invention

The present invention relates to a semiconductor device and a method of manufacturing the semiconductor device, and more particularly, to an anti-fuse structure of the semiconductor device.

2. Description of the Background Art

In a process of manufacturing a semiconductor device, an electrical test is performed for determining whether a semiconductor device is defective or non-defective. When the electrical test reveals defects in a semiconductor device, a circuit is modified by means of a fuse circuit or an antifuse circuit provided in the semiconductor device.

A conventional semiconductor device having an antifuse circuit will now be described.

FIG. 46 is a cross-sectional view for showing the conventional semiconductor device.

As shown in FIG. 46, reference numeral 51 designates a lower interconnection; 52 designates an interlayer dielectric film; 53 designates an antifuse film; and 54 designates an upper layer interconnection.

In the conventional semiconductor device (antifuse circuit), electrical stress is applied to the upper interconnection 54 (or the lower interconnection 51), thereby inducing a dielectric breakdown in the antifuse film 53. Thus, the lower interconnection 51 is electrically connected to the upper interconnection 54. As a result, connection of the antifuse circuit is established.

Another approach to establish connection of the antifuse circuit is to radiate a laser beam onto the upper interconnection 54 formed on the antifuse film 53. More specifically, a predetermined area on the upper interconnection 54 is subjected to laser blow, thereby inducing a dielectric breakdown in the antifuse film 53 and effecting connection of the antifuse circuit.

However, when connection of the antifuse circuit is effected by means of electrical stress, variations arise in a programming voltage in accordance with plasma damage (ion damage) which has arisen when the upper interconnection 54 is formed on the antifuse film 53.

Effecting connection of the antifuse circuit by means of producing the dielectric breakdown in the antifuse film 53 makes it impossible to ensure a sufficiently large area of a short-circuit section; namely, a sufficiently large area where the upper layer interconnection 54 and the lower interconnection 51 are to be connected together. For these reasons, the reliability of the antifuse circuit has been low.

When connection of the antifuse circuit is effected by means of laser blow, the energy of the laser beam may damage another interconnection layer provided on the bottom of the lower interconnection layer 51 or a semiconductor element. Hence, a semiconductor device suffers from low reliability.

Since an area to be exposed to the laser beam requires a certain amount of area, an increase in the packing density of a semiconductor element cannot be pursued.

### SUMMARY OF THE INVENTION

The present invention has been conceived to solve the previously-mentioned problems and a general object of the present invention is to provide a novel and useful semiconductor device.

A more specific object of the present invention is to provide a semiconductor device having an antifuse circuit of high reliability.

The above object of the present invention is attained by a following semiconductor device.

According to a first aspect of the present invention, the semiconductor device having a short circuit or a spare circuit for preventing application of a high voltage to a load circuit, comprises: a substrate; a first interconnection formed on the substrate and connected to the short circuit or the spare circuit; a first dielectric film for covering the first interconnection; an opening section for extending from a surface of the first dielectric film to the first interconnection, the opening section being formed in the first dielectric film; a plug formed in the opening section and electrically connected to the first interconnection; a second interconnection formed on the plug by way of a predetermined void and connected to the load circuit; and a second dielectric film for covering the second interconnection.

According to a second aspect of the present invention, the semiconductor device having a short circuit or a spare circuit for preventing application of a high voltage to a load circuit, comprises: a substrate; a first interconnection formed on the substrate and connected to the short circuit or the spare circuit; a first dielectric film for covering the first interconnection; an opening section for extending from a surface of the first dielectric film to the first interconnection, the opening section being formed in the first dielectric film; a plug formed in the opening section and electrically connected to the first interconnection; a second interconnection formed on the first dielectric film in the vicinity of the plug and connected to the load circuit; and a second dielectric film having a predetermined void located at a position adjacent to the second interconnection and at a position above the plug, the second dielectric film covering the second interconnection.

According to a third aspect of the present invention, the semiconductor device having a short circuit or a spare circuit for preventing application of a high voltage to a load circuit, comprises: a substrate; a first dielectric film formed on the substrate and having an opening section; a pad formed in the opening section and having conductivity; a first interconnection formed on the first dielectric film such that a portion of a bottom of the first interconnection comes into contact with an upper surface of the pad; a second interconnection formed on the first dielectric film such that a bottom surface of the second interconnection does not come into contact with the upper surface of the pad, the second interconnection being connected to the load circuit, the pad being disposed between the first and second interconnections; and a second dielectric film having a predetermined void located at a position on the pad, the second dielectric film covering the first and second interconnections.

Other objects and further features of the present invention will be apparent from the following detailed description when read in conjunction with the accompanying drawings.

### BRIEF DESCRIPTION OF THE DRAWINGS

FIG. 1 is a cross-sectional view for describing a semiconductor device according to a first embodiment of the present invention;

FIG. 2 is a top view for showing the positional relationships between a lower interconnection, a plug, and an upper interconnection provided in a semiconductor device according to a first embodiment of the present invention;

FIGS. 3 through 8 are views for describing a method of manufacturing a semiconductor device according to a first embodiment of the present invention;

FIG. 9 is a cross-sectional view for describing the connection of an antifuse circuit in a semiconductor device according to a first embodiment of the present invention;

FIG. 10 is a cross-sectional view for describing a semiconductor device according to a second embodiment of the present invention;

FIGS. 11 through 16 are views for describing a method of manufacturing a semiconductor device according to a second embodiment of the present invention;

FIG. 17 is a cross-sectional view for describing a semiconductor device according to a third embodiment of the present invention;

FIGS. 18 through 23 are views for described a method of manufacturing a semiconductor device according to a third embodiment of the present invention;

FIG. 24 is across-sectional view for describing a semiconductor device according to a fourth embodiment of the present invention;

FIG. 25 is a top view for showing the positional relationships between a lower interconnection, a plug, a void, and an upper interconnection in a semiconductor device according to a fourth embodiment of the present invention;

FIGS. 26 through 30 are views for describing a method of manufacturing a semiconductor device according to a fourth embodiment of the present invention;

FIG. 31 is a cross-sectional view for describing a semiconductor device according to a fifth embodiment of the present invention;

FIG. 32 is a top view for describing the positional relationships between a first interconnection, a pad, a void, and a second interconnection provided in a semiconductor device according to a fifth embodiment of the present invention;

FIGS. 33 through 37 are views for describing a method of manufacturing a semiconductor device according to a fifth embodiment of the present invention;

FIG. 38 is a cross-sectional view for describing another method of forming a second interconnection in connection with a method of manufacturing a semiconductor device according to a fifth embodiment of the present invention;

FIG. 39 is a cross-sectional view for describing a semiconductor device according to a sixth embodiment of the present invention;

FIGS. 40 through 45 are views for describing a method of manufacturing a semiconductor device according to a sixth embodiment of the present invention;

FIG. 46 is a cross-sectional view for showing a conventional semiconductor device.

### DETAILED DESCRIPTION OF THE PREFERRED EMBODIMENTS

In the following, principles and embodiments of the present invention will be described with reference to the accompanying drawings. The members and steps that are common to some of the drawings are given the same reference numerals and redundant descriptions therefore may be omitted.

### FIRST EMBODIMENT

A semiconductor device according to a first embodiment of the present invention will now be described.

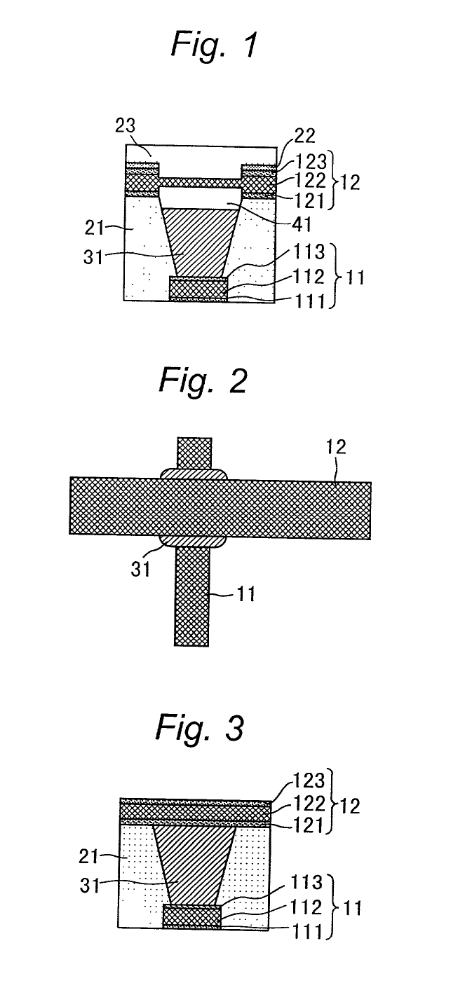

FIG. 1 is a cross-sectional view for describing a semiconductor device according to a first embodiment of the present invention. FIG. 2 is a view showing the positional relationships between a lower interconnection, a plug, and an upper interconnection provided in a semiconductor device according to a first embodiment of the present invention.

In FIGS. 1 and 2, reference numeral 11 designates a lower interconnection (first interconnection); 12 designates an upper interconnection (second interconnection); 21, 22, and 23 designate dielectric films; 31 designates a plug; and 41 designates a void.

The lower interconnection 11 comprises barrier metal layers 111 and 113 and an aluminum interconnection 112. The barrier metal layers 111 and 113 are formed from TiN, Ti, TaN, or Ta, or a stacked film thereof (the same also applies to another barrier metal layer to be described later). The aluminum interconnection 112 may be formed from solely Al or from an aluminum alloy consisting of AlSiCu or AlCu (the same also applies to another aluminum interconnection to be described later). The upper interconnection 12 has barrier metal layers 121 and 123 and an aluminum interconnection 122.

The upper interconnection 12 is connected to an unillustrated load circuit. The lower interconnection 11 is connected to an unillustrated short circuit or spare circuit.

As shown in FIG. 1, the lower interconnection 11 is formed on a substrate (not shown), and a dielectric film 21 is formed so as to cover the lower interconnection 11. An opening is formed in the dielectric film 21 so as to extend from the surface of the dielectric film 21 to an upper surface of the lower interconnection 11. A plug 31 is formed within the opening and electrically connected to the lower interconnection 11. Further, an upper interconnection 12 is formed above the plug 31. Here, a void 41 is formed between the plug 31 and the upper interconnection 12. In short, the upper interconnection 12 is formed on the plug 31 by way of the void 41, and the void 41 separates the upper interconnection 12 from the plug 31. The upper interconnection 12 is electrically insulated from the lower interconnection 11.

An operation of the semiconductor device will now be described. More specifically, connection of antifuse circuit in the semiconductor device will be described.

FIG. 9 is a cross-sectional view for describing connection of the antifuse circuit in the semiconductor device according to the first embodiment.

As shown in FIG. 9, when a predetermined voltage is applied to the upper interconnection 12, electromigration arises in the aluminum interconnection 122 of the upper interconnection 12. As a result, the aluminum interconnection 122 is connected to the plug 31 via the void 41 formed immediately below the aluminum interconnection 122. Since the plug 31 remains electrically connected to the lower interconnection 11, the upper interconnection 12 is electrically connected to the lower interconnection 11 via the plug 31. More specifically, the upper interconnection 12 and the lower interconnection 11 are subjected to antifuse interconnection.

A contact area ensured between the aluminum interconnection 122 and the plug 31 (i.e., the area of a short-circuited section) is wider than that ensured when antifuse connection is effected in a conventional semiconductor device.

The upper interconnection 12 is connected to the load circuit, and the lower interconnection 11 is connected to the short circuit or the spare circuit. Accordingly, a voltage sufficient for activating a load circuit is not applied to a load circuit.

A method of manufacturing the semiconductor device will now be described.

FIGS. 3 through 8 are illustrations for describing a method of manufacturing a semiconductor device according to a first embodiment of the present invention.

As shown in FIG. 3, a barrier metal layer 111, an aluminum interconnection 112, and a barrier metal layer 113 are stacked on a substrate (not shown), in the sequence given. Next, the thus-stacked barrier metal layers 111 and 113 and the aluminum interconnection 112 are patterned. As a result, a lower interconnection 11 consisting of the barrier metal layers 111 and 113 and the aluminum interconnection 112 is formed.

Next, by means of the plasma CVD technique a dielectric film (i.e., an interlayer dielectric film) 21 is formed over the entire surface of the substrate so as to cover the lower interconnection 11. By means of dry etching, an opening section is formed in the dielectric film 21 so as to extend from the surface of the dielectric film 21 to the lower interconnection 11.

The opening section is embedded with metal, such as tungsten, and unnecessary portion of metal (tungsten) is removed by CMP (chemical and mechanical polishing) operation. As a result, a plug (tungsten plug) 31 is formed in the opening section.

The barrier metal layer 121, the aluminum interconnection 122, and the barrier metal layer 123 are stacked on the dielectric film 21 and on the plug 31. The barrier metal layers 121 and 123 and the aluminum interconnection 122 are patterned. As a result, there is formed an upper interconnection 12 consisting of the barrier metal layers 121 and 123 and the aluminum interconnection 122.

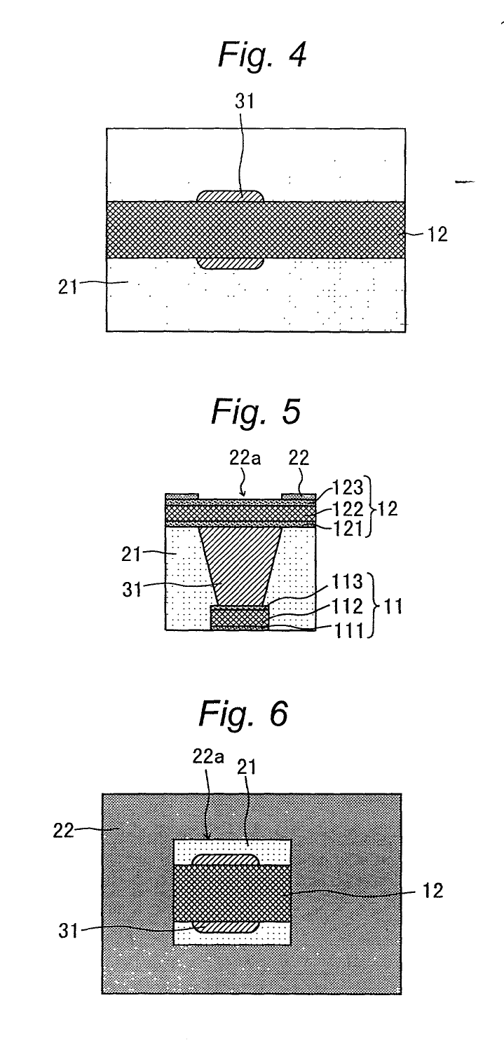

The plug 31 and the upper interconnection 12 are formed so as to assume a positional relationship shown in FIG. 4.

As shown in FIGS. 5 and 6, a dielectric film 22 is formed over the entire surface of the substrate so as to cover the upper interconnection 12. The dielectric film 22 formed above the plug 31 is removed by means of dry etching, thereby forming an opening section 22a in the dielectric film 22. Here, the opening section 22a is formed to be of greater area than the upper surface of the plug 31.

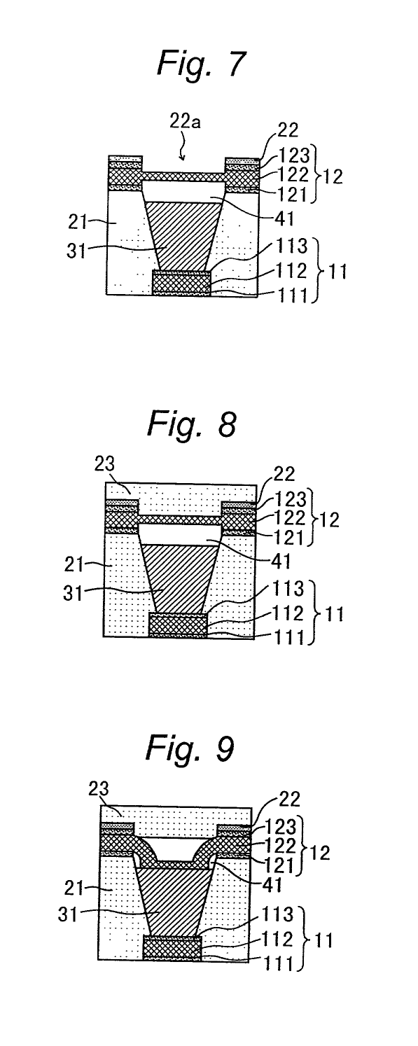

As shown in FIG. 7, a chemical solution is poured into the opening section 22a of the dielectric film 22, thereby wet-etching the barrier metal layer 121 and a lower portion of the aluminum interconnection 122, which are formed above the plug 31, and an upper-layer portion of the plug 31. Here, the chemical solution is an alkaline-based solution containing NH₄OH. The concentration of the alkaline-based solution is controlled so as not to dissolve all the aluminum interconnection 122 located in the vicinity of the opening section 22a.

As a result, a void 41 is formed above the plug 31. More specifically, the upper interconnection 12 is separated from the plug 31 by means of the void 41.

The barrier metal layer 123 and an upper portion of the aluminum interconnection 122 are removed through wet etching. Although not illustrated, the aluminum interconnection 122 is wet-etched even in a widthwise direction of the interconnection (i.e., a direction away from the viewer of FIG. 7). The width of the aluminum interconnection 122 becomes smaller at a position above the plug 31.

Finally, as shown in FIG. 8, a dielectric film (protective insulation film) 23 is formed by means of plasma CVD over the entire surface of the substrate so as to close the opening section 22a of the dielectric film 22.

As described above, in the first embodiment, a predetermined voltage is applied to the upper interconnection 12, thereby causing electromigration in the aluminum interconnection 122. As a result, the upper interconnection 12 and the plug 31, which have been separated from each other by means of the void 41, are interconnected. Since the plug 31 is electrically connected to the lower interconnection 11, the upper interconnection 12 is electrically connected to the lower interconnection 11 by way of the plug 31.

Accordingly, the upper interconnection 12 and the lower interconnection 11 can be subjected to antifuse connection by means of inducing electromigration in the upper interconnection 12. Accordingly, there can be prevented application, to the load circuit connected to the upper interconnection 12, of a voltage sufficient for activating the load circuit.

In the first embodiment, a contact area (i.e., the area of a short-circuited section) ensured between the aluminum interconnection 122 and the plug 31 is wider than that ensured in a case where dielectric breakdown arises in the conventional antifuse film. Further, the size of the void 41, which corresponds to a short-circuited portion, can be readily controlled by means of the extent of wet etching induced by the chemical solution.

Accordingly, antifuse connection can be effected without fail, thereby enabling a significant improvement in the reliability of an antifuse structure (antifuse circuit). Further, there can be suppressed variations in a programming voltage, which have arisen conventionally.

Lower and upper portions of the aluminum interconnection 122 are wet-etched, thereby reducing the thickness of the aluminum interconnection 122 locally (i.e., at a position above the plug 31). Concurrently, the width of the aluminum interconnection 122 becomes small. Hence, electromigration can be induced, with priority being placed on the thin (and narrow) portion of the aluminum interconnection 122.

In order to induce electromigration in the aluminum interconnection 122, a voltage applied to the upper interconnection 12 is lower than the conventional programming voltage. An applied voltage can be suppressed to, for example, 3V or less, depending on an applied pulse waveform. Accordingly, there is no necessity of applying an excessive voltage. As a result, the reliability of a semiconductor device can be improved (the same also applies to the second through sixth embodiments to be described later).

The void 41 is formed at a position immediately above the plug 31, and the aluminum interconnection 122 is formed at a position immediately above the void 41. Hence, the aluminum interconnection 122 where electromigration has arisen can be readily brought into contact with the plug 31. Hence, antifuse connection can be effected more reliably.

In the first embodiment, a short circuit is not induced by use of laser blow. Hence, an antifuse circuit can be connected without involvement of damage to a semiconductor element (the same also applies to the second through sixth embodiments to be described later).

In the semiconductor device according to the first embodiment, antifuse connection can be effected by means of merely applying a predetermined voltage to the upper interconnection 12. Even after a semiconductor device has been packaged, antifuse connection can be effected. Accordingly, manufacturing yield of the semiconductor device can be improved.

In the first embodiment, the void 41 is formed by means of removing the plug 31, the barrier metal layer 121, and the aluminum interconnection 122. Alternatively, a void may be formed by means of removing only the plug 31 and the barrier metal layer 121. More specifically, wet etching a lower portion of the aluminum interconnection 122 is not necessary. Even this case yields the same advantage as that mentioned previously.

### SECOND EMBODIMENT

In the first embodiment, the void 41 is formed by means of removing the plug 31, the barrier metal layer 121, and the aluminum interconnection 122 through wet etching. In a second embodiment, there is described a semiconductor device in which a void is formed by means of removing only a barrier metal layer through wet etching.

A semiconductor device according to a second embodiment will first be described.

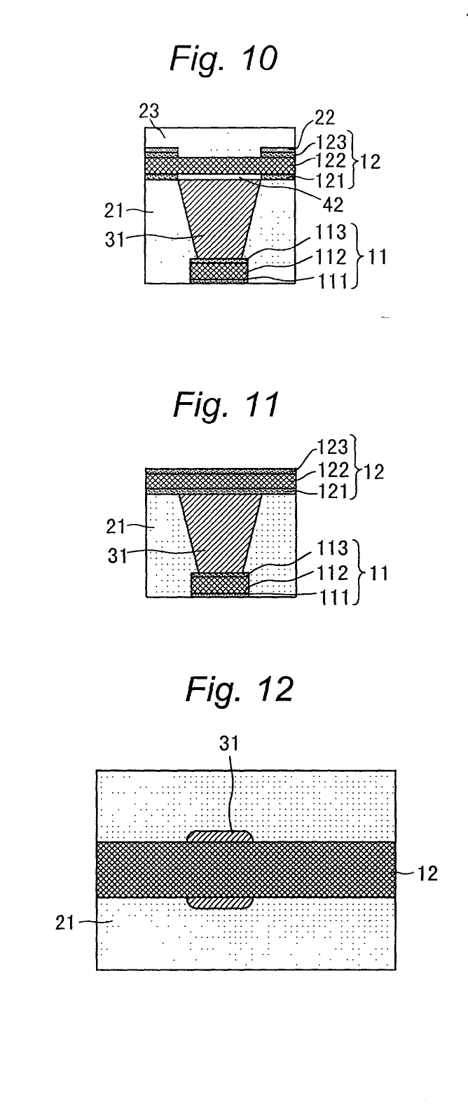

FIG. 10 is a cross-sectional view for describing a semiconductor device according to a second embodiment of the present invention. In FIG. 10, those reference numerals which are identical with those shown in FIG. 1 or 2 designate the same elements. Hence, repeated explanation thereof is simplified or omitted. Reference numeral 42 in FIG. 10 designates a void.

As shown in FIG. 10, the lower interconnection 11 is formed on a substrate (not shown), and the dielectric film 21 is formed so as to cover the lower interconnection 11. The plug 31 is formed in the opening section within the dielectric film 21, and the upper interconnection 12 is formed above the plug 31. Here, the void 42 is formed between the plug 31 and the upper interconnection 12. In short, the upper interconnection 12 is formed above the plug 31 via the void 42. The void 42 isolates the upper interconnection 12 from the plug 31. The upper interconnection 12 is electrically isolated from the lower interconnection 11. Here, the void 42 is formed by means of removing the barrier metal layer 121 (as will be described later).

Since the semiconductor device operates in the same manner as in the first embodiment, repeated explanation thereof is omitted.

A method of manufacturing the semiconductor device will next be described.

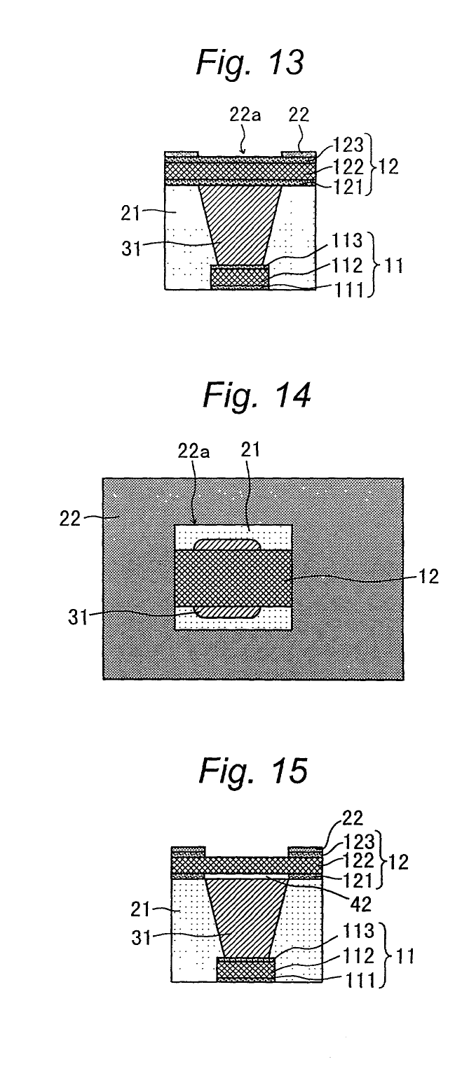

FIGS. 11 through 16 are views for describing a method of manufacturing the semiconductor device according to the second embodiment.

First, processing pertaining to steps shown in FIGS. 11 through 14 is performed. Since the steps shown in FIGS. 11 through 14 are identical with those shown in FIGS. 3 through 6 described in connection with the first embodiment, repeated explanations thereof are omitted.

Subsequently, as shown in FIG. 15, a chemical solution containing, e.g., hydrogen peroxide, is poured into the opening section 22a of the dielectric film 22, thereby wet-etching the barrier metal layer 121 formed on the plug 31. As a result, the void 42 is formed above the plug 31. Concurrently, the barrier metal layer 123 is eliminated by wet etching. However, such removal of the barrier metal layer 123 does not pose any problem in device operation.

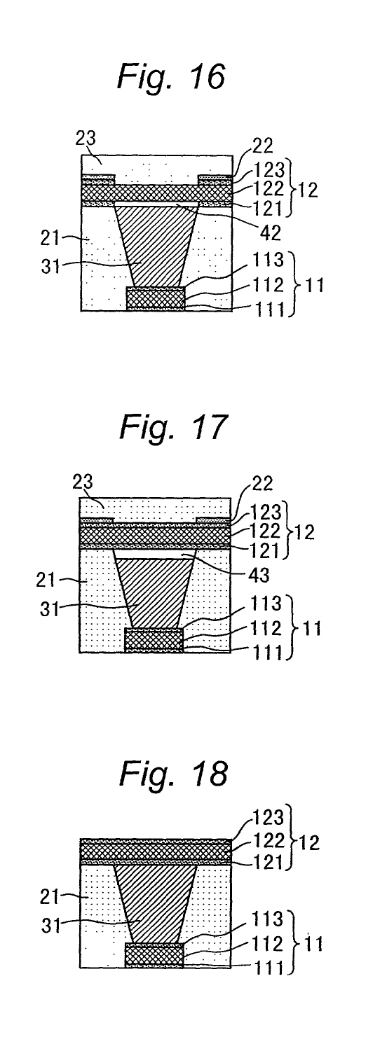

Finally, as shown in FIG. 16, a dielectric film (protective film) 23 is formed over the entire surface of the substrate by means of the plasma CVD technique so as to close the opening section 22a of the dielectric film 22.

As described above, in the second embodiment, a predetermined voltage is applied to the upper interconnection 12, thereby inducing electromigration in the aluminum interconnection 122. As a result, the upper interconnection 12 and the plug 31, which have been separated from each other by means of the void 42, are interconnected. Since the plug 31 is electrically connected to the lower interconnection 11, the upper interconnection 12 is electrically connected to the lower interconnection 11 by way of the plug 31.

Accordingly, the second embodiment yields the same advantage as that yielded in the first embodiment.

### THIRD EMBODIMENT

In the first embodiment, the plug 31, the barrier metal layer 121, and the aluminum interconnection 122 are removed through wet etching, thereby forming the void 41. In a third embodiment, there will be described a semiconductor device in which a void is formed by means of wet etching only an upper portion of the plug.

A semiconductor device according to the third embodiment will now be described.

FIG. 17 is a cross-sectional view for describing a semiconductor device according to the third embodiment.

In FIG. 17, those reference numerals which are identical with those shown in FIG. 1 or 2 designate the same elements. Hence, repeated explanations thereof are omitted or simplified. Reference numeral 43 shown in FIG. 17 designates a void.

As shown in FIG. 17, the lower interconnection 11 is formed on a substrate (not shown), and the dielectric film 21 is formed so as to cover the lower interconnection 11. The plug 31 is formed in an opening section within the dielectric film 21, and the upper interconnection 12 is formed above the plug 31. Here, a void 43 is formed between the plug 31 and the upper interconnection 12. More specifically, the upper interconnection 12 is formed above the plug 31 via the void 43. Therefore, the upper interconnection 12 is isolated from the plug 31 by means of the void 43, thereby electrically isolating the upper interconnection 12 from the lower interconnection 11. Here, the void 43 is formed by means of removing an upper portion of the plug 31 (as will be described later).

Since the semiconductor device operates in the same manner as in the first embodiment, repeated explanation thereof is omitted.

A method of manufacturing the semiconductor device will now be described.

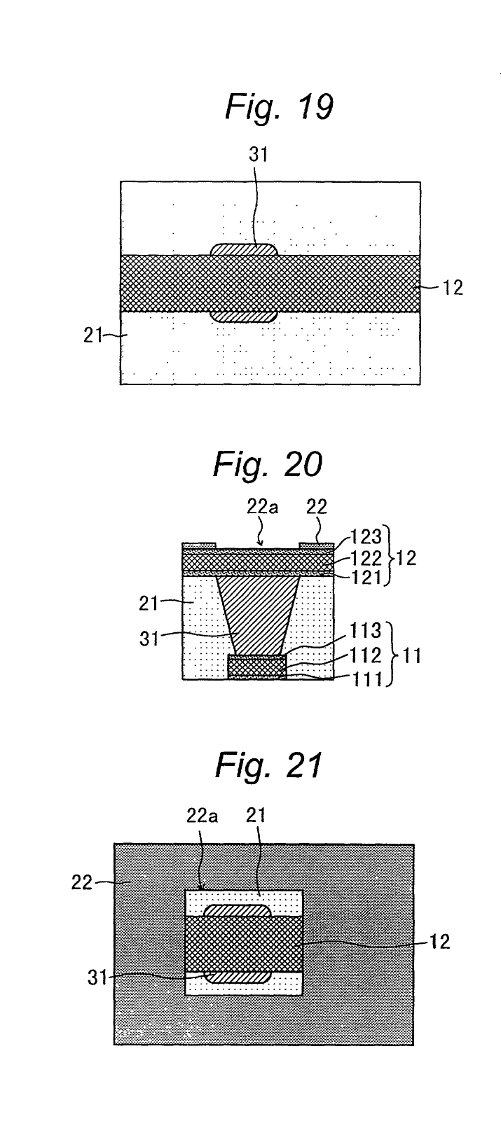

FIGS. 18 through 23 are views for described a method of manufacturing a semiconductor device according to the third embodiment.

First, processing pertaining to the steps shown in FIGS. 18 through 21 is carried out. Since the steps shown in FIGS. 18 through 21 are identical with those shown in FIGS. 3 through 6 described in connection with the first embodiment, repeated explanations thereof are omitted.

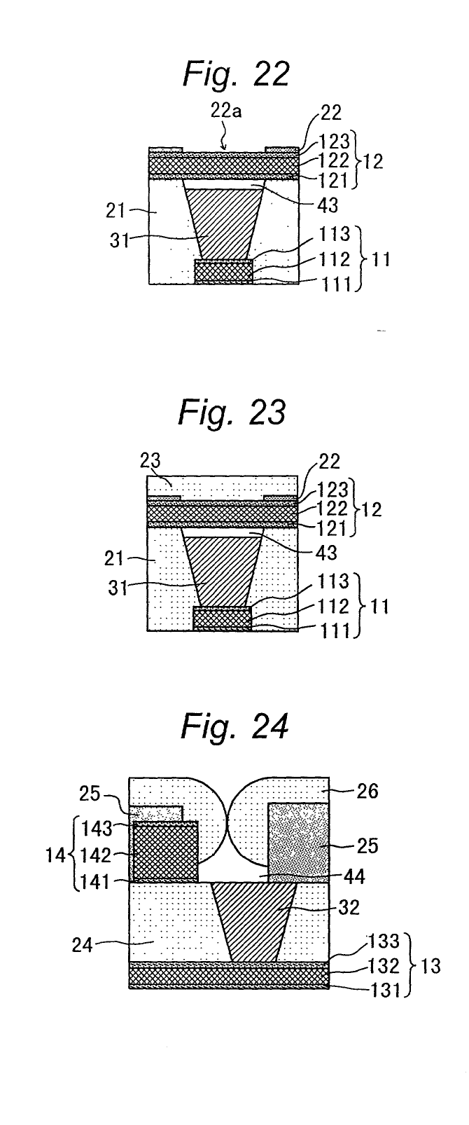

As shown in FIG. 22, a chemical solution made by mixing, e.g., Al anticorrosive into an NH₄O solution, is poured into the opening section 22a of the dielectric film 22, thereby removing an upper portion of the plug 31 through wet etching. As a result, the void 43 is formed above the plug 31. A barrier metal anticorrosive may be mixed into the chemical solution, as required.

Finally, as shown in FIG. 23, the dielectric film (protective dielectric film) 23 is formed by means of the plasma CVD technique so as to close the opening section 22a of the dielectric film 22.

As described above, in the third embodiment, a predetermined voltage is applied to the upper interconnection 12, thereby inducing electromigration in the aluminum interconnection 122. As a result, the upper interconnection 12 and the plug 31, which have been isolated from each other by means of the void 43, are interconnected. The plug 31 is electrically connected to the lower interconnection 11, and hence the upper interconnection 12 is electrically connected to the lower interconnection 11 by way of the plug 31.

Accordingly, the third embodiment yields the same advantage as that yielded in the first embodiment.

### FOURTH EMBODIMENT

A semiconductor device according to a fourth embodiment of the present invention will now be described.

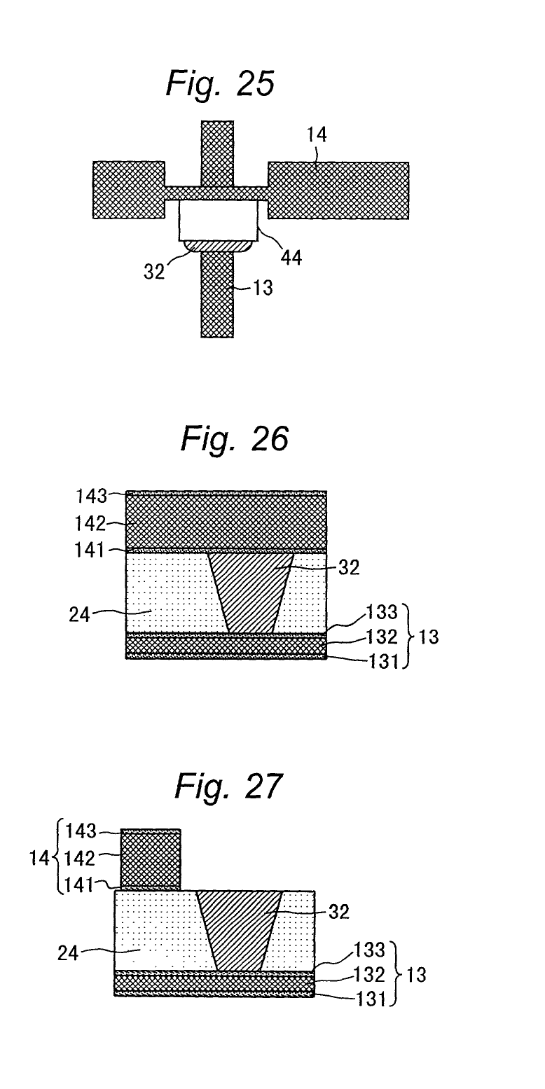

FIG. 24 is a cross-sectional view for describing a semiconductor device according to the fourth embodiment. FIG. 25 is a top view showing the positional relationships between a lower interconnection, a plug, a void, and an upper interconnection in the semiconductor device according to the fourth embodiment.

In FIGS. 24 and 25, reference numeral 13 designates a lower interconnection (first interconnection); 14 designates an upper interconnection (second interconnection); 24, 25, and 26 designate dielectric films; 32 designates a plug; and 44 designates a void.

The lower interconnection 13 has barrier metal layers 131 and 133 and an aluminum interconnection 132. The upper interconnection 14 has barrier metal layers 141 and 143 and an aluminum interconnection 142.

The upper interconnection 14 is connected to an unillustrated load circuit. In contrast, the lower interconnection 13 is connected to an unillustrated short circuit or spare circuit.

As shown in FIG. 24, the lower interconnection 13 is formed on a substrate (not shown), and the dielectric film 24 is formed so as to cover the lower interconnection 13. An opening section is formed in the dielectric film 24 so as to extend from the surface of the dielectric film 24 to the upper surface of the lower interconnection 13. A plug 32 is formed within the opening section. Here, the plug 32 is electrically connected to the lower interconnection 13.

The upper interconnection 14 is formed on the dielectric film 24. Here, the upper interconnection 14 is formed such that the bottom of the upper interconnection 14 does not come into contact with the upper surface of the plug 32. Further, the upper interconnection 14 is formed such that the width of the interconnection becomes small in the vicinity of the plug 32 (see FIG. 25).

The dielectric film 25 is formed over the entire surface of the substrate so as to cover the upper interconnection 14. An opening section (e.g., an opening section 25a to be described later) is formed in the dielectric film 25 so as to extend from the surface of the dielectric film 25 to the upper surface of the plug 32. Here, a portion of the upper interconnection 14 is exposed through the opening section.

The dielectric film (protective dielectric film) 26 is formed over the entire surface of the substrate so as to close the opening section. Here, the opening section is not fully embedded with the dielectric film 26, and a void 44 remains in the bottom of the opening section. More specifically, the upper interconnection 14 and the plug 32 are separated from each other by means of the void 44 formed in a position adjacent the upper interconnection 14 and a position above the plug 32.

An operation of the semiconductor device; that is, connection of an antifuse circuit, will now be described.

Although not illustrated, when a predetermined voltage is applied to the upper interconnection 14, electromigration arises in the aluminum interconnection 142 of the upper interconnection 14. As a result, the aluminum interconnection 142 is connected to the plug 32 via the void 44. Since the plug 32 is electrically connected to the lower interconnection 13, the upper interconnection 14 and the lower interconnection 13 are electrically connected together through the plug 32 (to form an antifuse connection).

Now, the contact area (i.e., the area of a short circuit section) ensured between the aluminum interconnection 142 and the plug 32 is wider than that ensured when antifuse connection is effected in the conventional semiconductor device.

The upper interconnection 14 is connected to a load circuit, and the lower interconnection 13 is connected to a short circuit or a spare circuit. Hence, a voltage sufficient for activating the load circuit is not applied to the load circuit.

Next will be described a method of manufacturing the foregoing semiconductor device.

FIGS. 26 through 30 are views for describing a method of manufacturing the semiconductor device according to the fourth embodiment.

As shown in FIG. 26, the barrier metal layer 131, the aluminum interconnection 132, and the barrier metal layer 133 are stacked on a substrate (not shown). Next, the thus-stacked barrier metal layers 131 and 133 and the aluminum interconnection 132 are patterned. As a result, the lower interconnection 13 is formed from the barrier metal layers 131 and 133 and the aluminum interconnection 132.

By means of the plasma CVD technique, the dielectric film (interlayer dielectric film) 24 is formed over the entire surface of the substrate so as to cover the lower interconnection 13. The opening section extending from the surface of the dielectric film 24 to the lower interconnection 13 is formed in the dielectric film 24 through dry etching.

The opening section is embedded with metal, such as tungsten, and unnecessary portion of metal (tungsten) is removed by means of CMP. As a result, the plug (tungsten plug) 32 is formed in the opening section.

Next, the barrier metal layer 141 is formed over the entire surface (i.e., the dielectric film 24 and the upper surface of the plug 32). The aluminum interconnection 142 is formed on the barrier metal layer 141, and the barrier metal layer 143 is formed on the aluminum interconnection 142.

As shown in FIG. 27, the barrier metal layers 141 and 143 and the aluminum interconnection 142 are patterned. As a result, there is formed an upper interconnection 14 consisting of the barrier metal layers 141 and 143 and the aluminum interconnection 142.

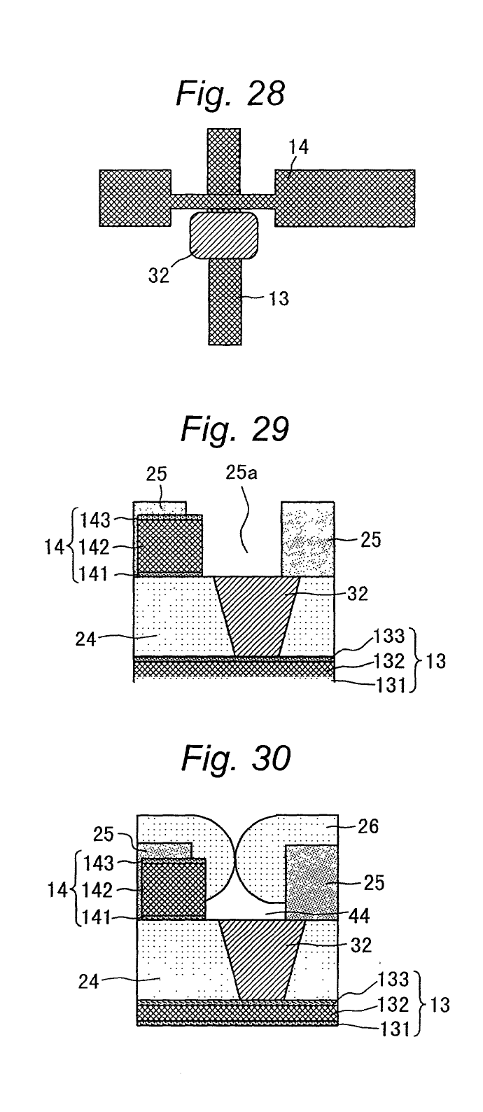

The lower interconnection 13, the upper interconnection 14, and the plug 32 are formed so as to assume positional relationships shown in FIG. 28. As shown in FIG. 28, the upper interconnection 14 is formed so as to become narrow in the vicinity of the plug 32. As a result, electromigration develops, with priority being placed on the area of the upper interconnection 14 in the vicinity of the plug 32.

As shown in FIG. 29, by means of the plasma CVD technique, the dielectric film 25 is formed over the entire surface of the substrate so as to cover the upper interconnection 14. The dielectric film 25 formed in the vicinity of the plug 32 is removed through etching. As a result, the opening section 25a is formed in the dielectric film 25, such that the upper surface of the plug 32 becomes exposed on the bottom surface of the opening section 25a. Further, a portion of the upper interconnection 14 is exposed by way of the opening section 25a.

Finally, as shown in FIG. 30, the dielectric film (protective dielectric film) 26 is formed by means of the plasma CVD technique over the entire surface of the substrate so as to close the opening section 25a. At this time, the opening section 25a is not embedded completely. The dielectric film 26 is formed such that a void 44 is left so as to extend from the side of the upper interconnection layer 14 to a position above the plug 32.

As described above, in the fourth embodiment, a predetermined voltage is applied to the upper interconnection 14, thereby inducing electromigration in the aluminum interconnection 142. As a result, the upper interconnection 14 and the plug 32, which have been separated from each other by means of the void 44, are interconnected. Since the plug 32 is electrically connected to the lower interconnection 13, the upper interconnection 14 is electrically connected to the lower interconnection 13 by way of the plug 32.

By means of inducing electromigration in the upper interconnection 14, the upper interconnection 14 and the lower interconnection 13 can be subjected to antifuse connection. Accordingly, there can be prevented application, to the load circuit connected to the upper interconnection 14, a voltage sufficient for activating the load circuit.

A contact area (i.e., the area of a short circuit section) ensured between the aluminum interconnection 142 and the plug 32 is wider than that ensured when the conventional antifuse film is subjected to dielectric breakdown. Hence, antifuse connection can be effected without fail, and the reliability of an antifuse structure can be improved significantly.

By means of making narrow the area of the upper interconnection 14 located in the vicinity of the plug 32, electromigration can be induced, with priority being placed on the vicinity of the plug 32 (the same also applies to the sixth embodiment to be described later).

In the semiconductor device according to the fourth embodiment, antifuse connection can be effected by means of merely applying a predetermined voltage to the upper interconnection 14. Hence, even after the semiconductor device has been packed, antifuse connection can be effected. Accordingly, manufacturing yield of the semiconductor device can be improved.

### FIFTH EMBODIMENT

A semiconductor device according to a fifth embodiment of the present invention will now be described.

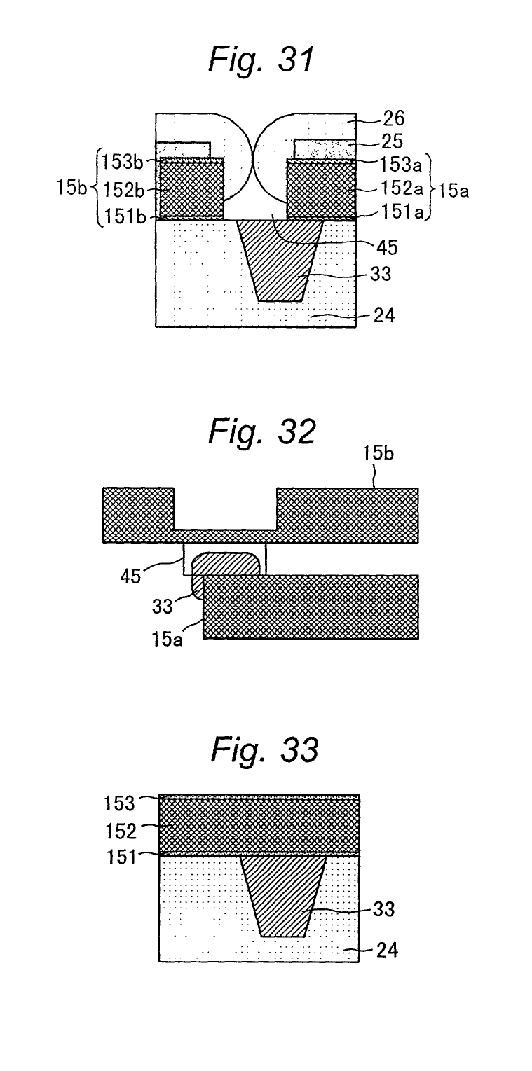

FIG. 31 is a cross-sectional view for describing a semiconductor device according to the fifth embodiment. FIG. 32 is a top view for describing the positional relationships between a first interconnection, a pad, a void, and a second interconnection provided in the semiconductor device according to the fifth embodiment.

In FIGS. 31 and 32, reference numeral 15a designates a first interconnection; 15b designates a second interconnection; 24, 25, and 26 designate dielectric films; 33 designates a pad; and 45 designates a void.

The first interconnection 15a comprises barrier metal layers 151a and 153a, and an aluminum interconnection 152a. A second interconnection 15b comprises barrier metal layers 151b and 153b and an aluminum interconnection 152b.

The first interconnection 15a is connected to an unillustrated short circuit or spare circuit, and the second interconnection 15b is connected to an unillustrated load circuit.

As shown in FIG. 31, the dielectric film 24 having, an opening section is formed on a substrate (not shown), and the pad 33 is formed within the opening section. The first interconnection 15a and the second interconnection 15b are formed on the dielectric film 24. Here, the first interconnection 15a is formed such that a portion of the bottom surface of the first interconnection 15a comes into contact with an upper surface of the pad 33. Further, the second interconnection 15b is formed such that the bottom of the second interconnection 15b does not come into contact with the upper surface of the pad 33. As shown in FIG. 32, the second interconnection 15b is formed so as to become narrow in a position in the vicinity of the pad 33. Further, the first interconnection 15a and the second interconnection 15b are formed such that the pad 33 is interposed therebetween.

The dielectric film 25 is formed so as to cover the first interconnection 15a and the second interconnection 15b. An opening section (i.e., an opening section 25a to be described later) is formed in the dielectric film 25 so as to extend from the surface of the dielectric film 25 to the upper surface of the pad 33. A portion of the first interconnection 15a and a portion of the second interconnection 15b are exposed through the opening section. If a portion of the second interconnection 15b is exposed through the opening section, the first interconnection 15a does not need to be exposed.

The dielectric film (protective dielectric film) 26 is formed so as to close the opening section of the dielectric film 25. Here, the opening section is not fully embedded with the dielectric film 26, and the void 45 remains in the bottom of the opening section. More specifically, the void 45 is formed in a position adjacent the second interconnection 15b and a position above the plug 33.

Next will be described an operation of the semiconductor device; that is, antifuse connection.

Although not illustrated, when a predetermined voltage is applied to the second interconnection 15b, electromigration arises in the aluminum interconnection 152b of the second interconnection 15b. As a result, the aluminum interconnection 152b is connected to the pad 33 via the void 45 formed on the pad 33. Since the pad 33 is electrically connected to the first interconnection 15a, the first interconnection 15b and the second interconnection 15b are electrically connected together (to form an antifuse connection) by way of the pad 33.

Next will be described a method of manufacturing the foregoing semiconductor device.

FIGS. 33 through 37 are views for describing a method of manufacturing the semiconductor device according to the fifth embodiment.

As shown in FIG. 33, by means of the plasma CVD technique, the dielectric film 24 is formed on a substrate (not shown). An opening section is formed in the dielectric film 24 to a predetermined depth through dry etching. The opening section is embedded with metal, such as tungsten. Unnecessary portion of metal (tungsten) is removed by means of CMP. As a result, the conductive pad 33 is formed in the opening section.

Next, a barrier metal layer 151 is formed over the entire surface. An aluminum interconnection 152 is formed on the barrier metal layer 151, and a barrier metal layer 153 is formed on the aluminum interconnection 152.

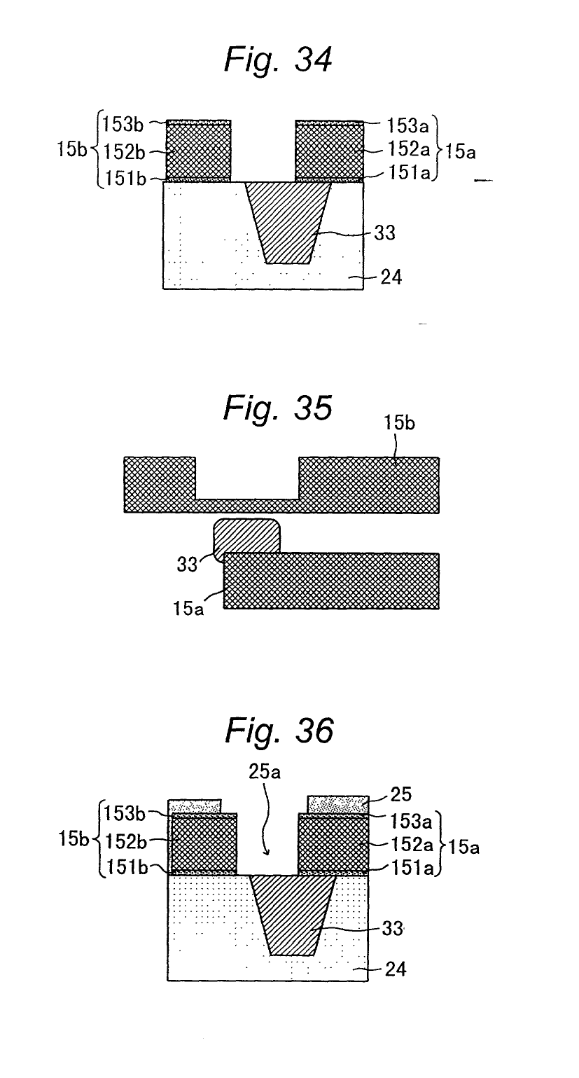

As shown in FIG. 34, the barrier metal layers 151 and 153 and the aluminum interconnection 152 are patterned. As a result, the first interconnection 15a and the second interconnection 15b are formed simultaneously within a single layer on the dielectric film 24.

The first interconnection 15a, the second interconnection 15b, and the pad 33 are formed so as to assume positional relationships shown in FIG. 35. As shown in FIG. 35, the second interconnection 15b is formed so as to become narrow in the vicinity of the pad 33. Hence, electromigration develops, with priority being placed on the area of the second interconnection 15b in the vicinity of the pad 33.

As shown in FIG. 36, by means of the plasma CVD technique, the dielectric film 25 is formed over the entire surface of the substrate so as to cover the first interconnection 15a and the second interconnection 15b. The dielectric film 25 formed in the vicinity of the pad 33 is removed through dry etching. As a result, the opening section 25a is formed in the dielectric film 25 so as to extend from the surface of the dielectric film 25 to the upper surface of the pad 33. A portion of the first interconnection 15a and a portion of the second interconnection 15b are exposed through the opening section 25a.

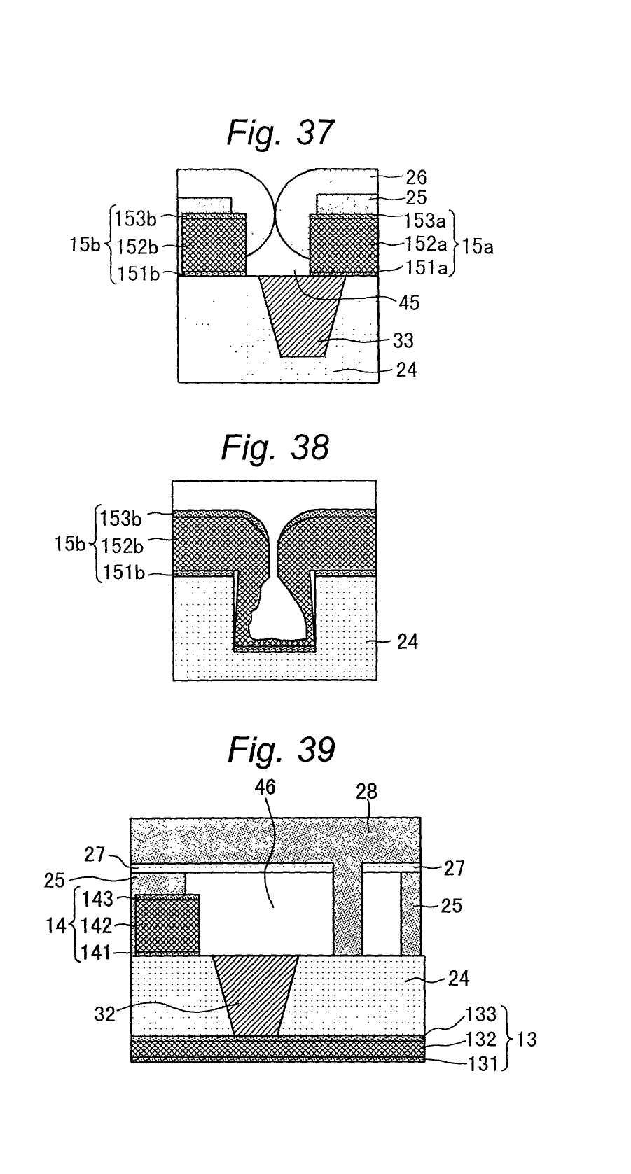

Finally, as shown in FIG. 37, the dielectric film (protective dielectric film) 26 is formed by means of the plasma CVD technique over the entire surface of the substrate so as to close the opening section 25a. At this time, the opening section 25a is not embedded fully. The dielectric film 26 is formed such that the void 45 remains in the bottom of the opening section 25a.

As described above, in the fifth embodiment, a predetermined voltage is applied to the second interconnection 15b, thereby inducing electromigration in the aluminum interconnection 152b of the second interconnection 15b. As a result, the second interconnection 15b and the pad 33, which have been separated from each other by means of the void 45, are interconnected. Since the pad 33 is electrically connected to the first interconnection 15a, the second interconnection 15b is electrically connected to the first interconnection 15a by way of the pad 33.

By means of inducing electromigration in the second interconnection 15b, the first interconnection 15a and the second interconnection 15b can be subjected to antifuse connection. Accordingly, there can be prevented application, to the load circuit connected to the second interconnection 15b, a voltage sufficient for activating the load circuit.

A contact area (i.e., the area of a short circuit section) ensured between the aluminum interconnection 152b and the pad 33 is wider than that ensured when the conventional antifuse film is subjected to dielectric breakdown. Hence, antifuse connection can be effected without fail, and the reliability of an antifuse structure can be improved significantly.

By means of making narrow the area of the second interconnection 15b located in the vicinity of the pad 33, electromigration can be induced, with priority being placed on the vicinity of the pad 33.

In the semiconductor device according to the fifth embodiment, antifuse connection can be effected by means of merely applying a predetermined voltage to the second interconnection 15b. Hence, even after the semiconductor device has been packed, antifuse connection can be effected. Accordingly, manufacturing yield of the semiconductor device can be improved.

The second interconnection 15b may be formed according to the following method rather than by the patterning method set forth. FIG. 38 is a cross-sectional view for describing another method of forming the second interconnection in connection with the method of manufacturing a semiconductor device according to the fifth embodiment.

As shown in FIG. 38, a trench is formed in the dielectric film 24. Here, the trench is formed in the vicinity of the pad 33. The trench is then embedded with the barrier metal layer 151b, the aluminum interconnection 152b, and the barrier metal layer 153b. As a result, the second interconnection 15b is formed on the dielectric film 24 and in the trench.

The second interconnection 15b formed along the side surface of the trench is narrow. As in a case where an interconnection is patterned, the second interconnection 15b becomes narrow in the vicinity of the pad 33. Accordingly, there is obviated a necessity for employing a sophisticated technique for miniaturizing the second interconnection 15b.

This method is preferable for use when the second interconnection 15b is thick; that is, in a case where difficulty is encountered in etching the aluminum interconnection 152b. The method is also preferable for use in a case where difficulty is encountered in locally narrowing an interconnection during transfer of a pattern employing the photolithography technique. Greatly changing the sizes of adjacent interconnections (or an interval between interconnections) on a single layer is difficult, and the method is particularly preferable for use in such a situation.

The method is also applicable to a case where the upper interconnection 14b is formed in the fourth and sixth embodiments.

### SIXTH EMBODIMENT

In the fourth embodiment, the void 44 is formed in a position adjacent to the upper interconnection 14 by embedding the opening section 25a again. The upper interconnection 14 is connected to the plug 32 via the void 44, thereby effecting antifuse connection.

A sixth embodiment provides a semiconductor device which obviates a necessity of embedding an opening section again during formation of a void, and also provides a method of manufacturing the semiconductor device.

A semiconductor device according to the sixth embodiment will first be described.

FIG. 39 is a cross-sectional view for describing the semiconductor device according to the sixth embodiment of the present invention.

As shown in FIG. 39, those reference numerals which are the same as those shown in FIG. 24 designate the same elements, and explanations thereof are simplified or omitted. In FIG. 39, reference numerals 27 and 28 designate dielectric films, and 46 designates a void.

As shown in FIG. 39, the lower interconnection 13 is formed on a substrate (not shown), and the dielectric film 24 is formed so as to cover the lower interconnection 13. An opening section is formed within the dielectric film 24, and a plug 32 is formed in the opening section.

The upper interconnection 14 is formed on the plug 32 (i.e., the dielectric film 24) Here, the upper interconnection 14 is formed such that the bottom of the upper interconnection 14 does not come into contact with an upper surface of the plug 32.

The dielectric film 25 is formed so as to cover the upper interconnection 14. Further, the dielectric film 27 is formed on the dielectric film 25, and an opening section (an opening section 27a to be described later) is formed within the dielectric film 27 at portions immediately below which no plug 32 is formed. In the dielectric film 25, there is formed an opening section (i.e., the opening section 25a to be described later) such that a portion of the upper surface of the plug 32 and a portion of the upper interconnection 14 are exposed. The dielectric film 25 differs in etch rate (wet-etching rate) from the dielectric film 27.

A dielectric film (i.e., a protective dielectric film) 28 is formed over the entire surface of the substrate so as to close the opening section of the dielectric film 27. The opening section of the dielectric film 25 is not fully embedded with the dielectric film 28, and a void 46 is formed in a position adjacent to the upper interconnection 14 and a position above the plug 32.

Antifuse connection in the semiconductor device will now be described.

Although not illustrated, when a predetermined voltage is applied to the interconnection 14, electromigration arises in the aluminum interconnection 142. As a result, the aluminum interconnection 142 is connected to the plug 32 via the void 46 formed in an adjacent position. The plug 32 is electrically connected to the lower interconnection 13, and hence the upper interconnection 14 and the lower interconnection 13 are electrically connected together (to form an antifuse connection) by way of the plug 32.

Next will be described a method of manufacturing the foregoing semiconductor device.

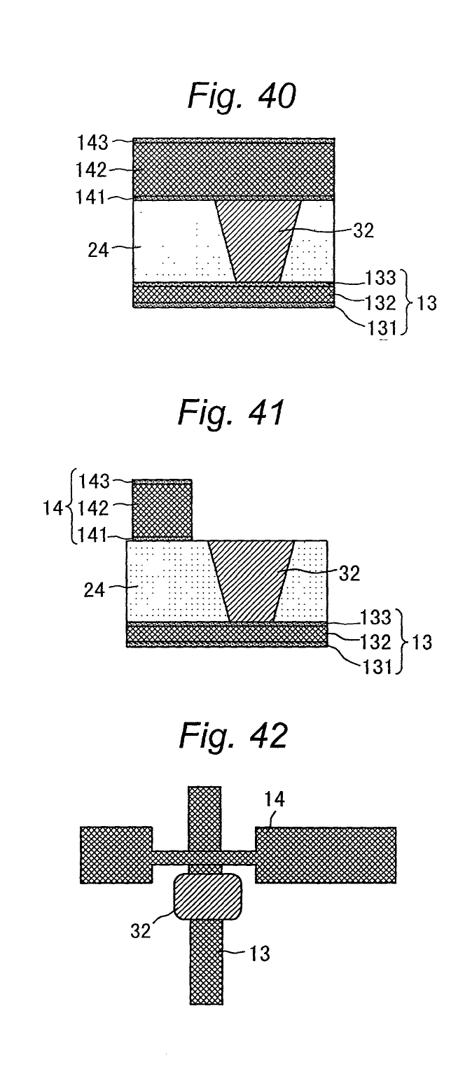

FIGS. 40 through 45 are views for describing a method of manufacturing the semiconductor device according to the sixth embodiment.

First, processing pertaining to the steps shown in FIGS. 40 and 41 is carried out. Since the steps shown in FIGS. 40 and 41 are identical with those shown in FIGS. 26 and 27 described in connection with the fourth embodiment, repeated explanations thereof are omitted.

When processing pertaining to the step shown in FIG. 41 is completed, the lower interconnection 13, the upper interconnection 14, and the plug 32 are formed so as to assume positional relationships shown in FIG. 42. As shown in FIG. 42, the upper interconnection 14 is formed so as to become narrower in the vicinity of the plug 32.

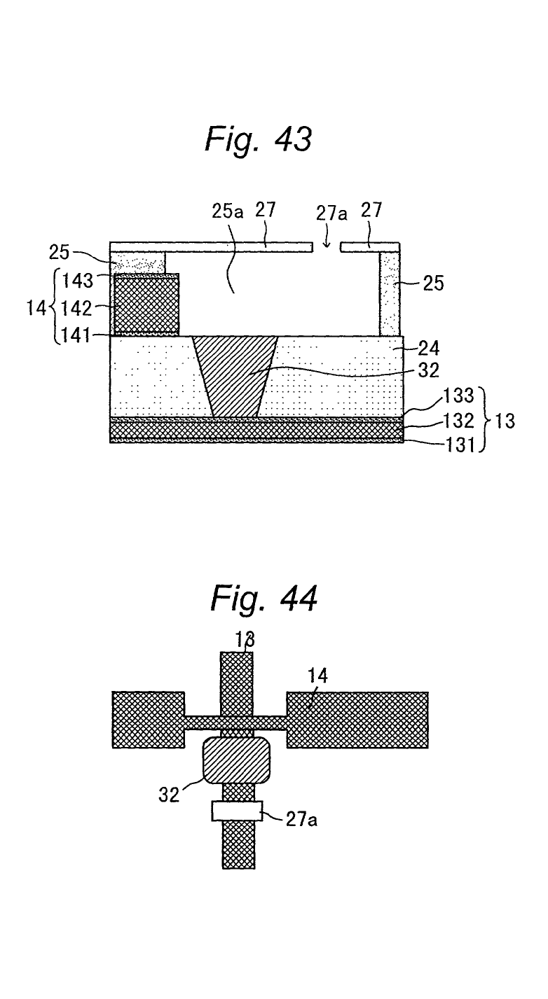

As shown in FIG. 43, the dielectric film 25 is formed over the entire surface of the substrate so as to cover the upper interconnection 14. A dielectric film 27 differing in etch rate (in wet-etching rate) from the dielectric film 25 is formed on the dielectric film 25. The etch rates of the dielectric films 25 and 27 are controlled in accordance with whether or not dopants are to be introduced into the dielectric films 25 and 27, as well as the types and amounts of dopants.

The dielectric film 27 formed in a position other than a position immediately above the plug 32 is removed by means of dry etching, thereby forming an opening section (i.e., an antifuse opening section) 27a (see FIG. 44).

A chemical solution is poured into the opening section 27a, thereby subjecting the dielectric film 25 to wet etching. As a result, the opening section 25a is formed in the dielectric film 25. Here, the chemical solution employed for wet etching is one which dissolves only the dielectric film 25. Further, a portion of the upper surface of the plug 32 and a portion of the upper interconnection 14 are exposed through the opening section 25a.

The lower interconnection 13, the upper interconnection 14, the antifuse opening section 27a, and the plug 32 are formed so as to assume positional relationships shown in FIG. 44.

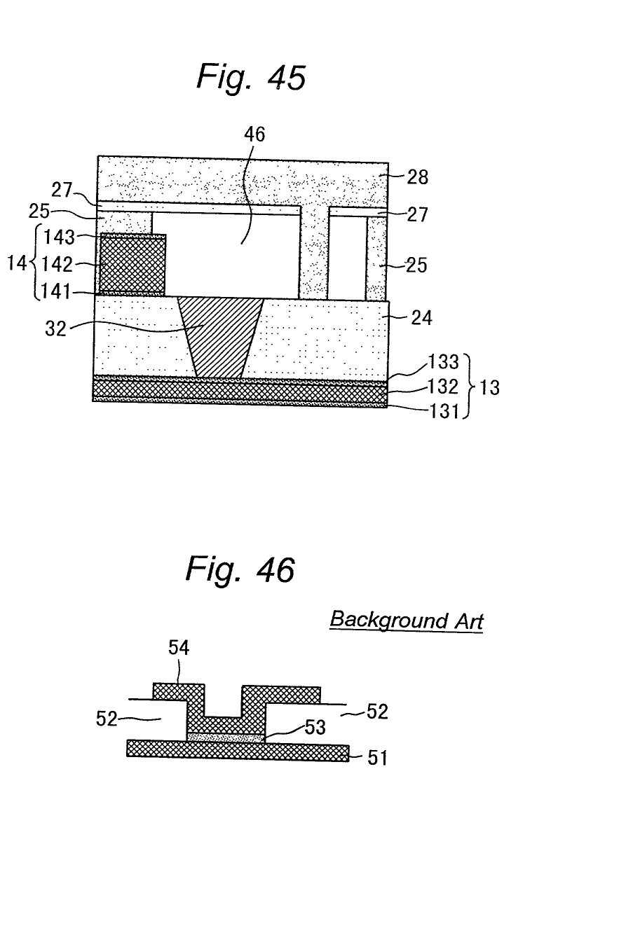

As shown in FIG. 45, the dielectric film 28 is formed over the entire surface of the substrate, whereby the void 46 is formed in the vicinity of the plug 32. Although the dielectric film 28 is formed also in the opening section 25a by way of the opening section 27a, the dielectric film 28 is not formed on the plug 32, because the opening section 27a is not located at a position immediately above the plug 32.

As described above, in the sixth embodiment, electromigration is induced in the aluminum interconnection 142 by means of applying a predetermined voltage to the upper interconnection 14. As a result, the upper interconnection 14 and the plug 32, which are separated from each other by means of the void 46, are interconnected. Since the plug 32 is electrically connected to the lower interconnection 13, the upper interconnection 14 is electrically connected to the lower interconnection 13 by way of the plug 32.

In the sixth embodiment, there is yielded the same advantage as that yielded in the fourth embodiment.

In the sixth embodiment, the two types of dielectric films 25 and 27 having different wet etch rates are formed. The chemical solution is poured into the opening section 27a, which is not located above the plug 32, thereby subjecting the dielectric film 25 to wet etching. Thus, the void 46 is formed.

Accordingly, there is no necessity of embedding the opening section again, which is required in the fourth embodiment. Therefore, a void can be formed more easily than in the fourth embodiment.

Also, to summarize the above-described method of manufacturing a semiconductor device, a first method of manufacturing a semiconductor device having a short circuit or a spare circuit for preventing application of a high voltage to a load circuit, comprises the steps of: forming a first interconnection on a substrate, the first interconnection being connected to the short circuit or the spare circuit; forming a first dielectric film on the entire surface of the substrate so as to cover the first interconnection; forming, within the first dielectric film, a first opening section which extends from a surface of the first dielectric film to the first interconnection; forming a plug in the first opening section; forming a void between the second interconnection and the plug; and forming a second dielectric film so as to cover the entire surface of the substrate after formation of the void.

In the first method, the second interconnection has a barrier metal layer and an aluminum interconnection formed on the barrier metal layer, and the void is formed by means of removing the barrier metal layer formed on the plug and an upper portion of the plug. In the first method, the void is formed by means of further removing a lower portion of the aluminum interconnection formed on the plug.

In the first method, the second interconnection has a barrier metal layer and an aluminum interconnection formed on the barrier metal layer, and the void is formed by means of removing the barrier metal layer formed on the plug.

In the first method, the second interconnection has a barrier metal layer and an aluminum interconnection formed on the barrier metal layer, and the void is formed by means of removing an upper portion of the plug.

In the first method, the void is formed by means of wet etching.

A second method of manufacturing a semiconductor device having a short circuit or a spare circuit for preventing application of a high voltage to a load circuit, comprises the steps of: forming a first interconnection on a substrate, the first interconnection being connected to the short circuit or the spare circuit; forming a first dielectric film on the entire surface of the substrate so as to cover the first interconnection; forming a first opening section within the first dielectric film; forming a plug in the first opening section; forming a second interconnection on the first dielectric film such that a portion of a bottom of the second interconnection overlaps an upper surface of the plug; forming a second dielectric film on the entire surface of the substrate so as to cover the second interconnection; forming in the second dielectric film a second opening section which extends from a surface of the second dielectric film to an upper surface of the plug, thereby enabling exposure of a portion of the second interconnection; and forming a third dielectric film over the entire surface of the substrate such that a void remains in a bottom of the second opening section.

A third method of manufacturing a semiconductor device having a short circuit or a spare circuit for preventing application of a high voltage to a load circuit, comprises the steps of: forming a first dielectric film on a substrate; forming a first opening section in the first dielectric film; forming a pad in the first opening section; forming a first interconnection on the first dielectric film, the first interconnection being connected to the short circuit or the spare circuit, such that a portion of a bottom of the first interconnection overlaps an upper surface of the pad; forming a second interconnection on the first dielectric film, the second interconnection being connected to the load circuit, such that a bottom surface of the second interconnection does not overlap the upper surface of the pad; forming a second dielectric film over the entire surface of the substrate so as to cover the first and second interconnections; forming a second opening section in the second dielectric film which extends from a surface of the second dielectric film to the upper surface of the pad, thereby enabling exposure of a portion of the second interconnection; and forming a third dielectric film over the entire surface of the substrate such that a void remains in a bottom section of the second opening section.

A fourth method of manufacturing a semiconductor device having a short circuit or a spare circuit for preventing application of a high voltage to a load circuit, comprises the steps of: forming a first interconnection on a substrate, the first interconnection being connected to the short circuit or the spare circuit; forming a first dielectric film over the entire surface of the substrate so as to cover the first interconnection; forming a first opening section in the first dielectric film; forming a plug in the first opening section; forming a second interconnection on the first dielectric film such that a bottom surface of the second interconnection does not overlap the upper surface of the plug; forming a second dielectric film over the entire surface of the substrate so as to cover the second interconnection; forming a third dielectric film on the second dielectric film; forming a second opening section in the third dielectric film which is not formed at a position located immediately above the plug; forming a void in a position adjacent to the second interconnection and at a position above the plug, by means of removing the second dielectric film exposed on the bottom section of the second opening section; and forming a fourth dielectric film over the entire surface of the substrate so as to close the second opening section.

This invention, when practiced illustratively in the manner described above, provides the following major effects:

According to the present invention, electromigration is induced in the upper interconnection or the second interconnection connected to the load circuit, thereby connecting the lower interconnection or the second interconnection to a plug or a pad by way of a void located in the vicinity of the upper interconnection or the second interconnection. A plug or pad is connected to the lower interconnection or the first interconnection, and the lower interconnection or the first interconnection is connected to the short circuit or the spare circuit.

Accordingly, a short circuit section of great area can be obtained. Hence, there can be provided a semiconductor device having an antifuse circuit of high reliability.

Further, the present invention is not limited to these embodiments, but variations and modifications may be made without departing from the scope of the present invention.

The entire disclosure of Japanese Patent Application No. 2001-183766 filed on Jun. 18, 2001 containing specification, claims, drawings and summary are incorporated herein by reference in its entirety.

What is claimed is

1. A semiconductor device having a short circuit or a spare circuit for preventing application of a high voltage to a load circuit, comprising:
a substrate;
a first interconnection formed on said substrate and connected to the short circuit or the spare circuit;
a first dielectric film for covering said first interconnection;
an opening section for extending from a surface of the first dielectric film to said first interconnection, said opening section being formed in said first dielectric film;
a plug formed in said opening section and electrically connected to said first interconnection;
a second interconnection formed on said plug by way of a predetermined void and connected to the load circuit; and
a second dielectric film for covering said second interconnection.

2. The semiconductor device according to claim 1,
wherein said second interconnection has a barrier metal layer and an aluminum interconnection formed on the barrier metal layer, and
the void is formed by means of removing an upper portion of said plug and the barrier metal layer formed on the upper portion of said plug.

3. The semiconductor device according to claim 2, wherein the void is formed by means of further removing a lower portion of the aluminum interconnection formed above said plug.

4. The semiconductor device according to claim 1, wherein said second interconnection has a barrier metal layer and an aluminum interconnection formed on the barrier metal layer, and
the void is formed by means of removing the barrier metal layer formed on said plug.

5. The semiconductor device according to claim 1, wherein said second interconnection has a barrier metal layer and an aluminum interconnection formed on the barrier metal layer, and
the void is formed by means of removing an upper portion of said plug.

6. A semiconductor device having a short circuit or a spare circuit for preventing application of a high voltage to a load circuit, comprising:
a substrate;
a first interconnection formed on said substrate and connected to the short circuit or the spare circuit;
a first dielectric film for covering said first interconnection;
an opening section for extending from a surface of said first dielectric film to said first interconnection, said opening section being formed in said first dielectric film;
a plug formed in said opening section and electrically connected to said first interconnection;
a second interconnection formed on said first dielectric film in the vicinity of said plug and connected to the load circuit; and
a second dielectric film having a predetermined void located at a position adjacent to said second interconnection and at a position above said plug, said second dielectric film covering said second interconnection.

7. The semiconductor device according to claim 6, wherein said second interconnection is formed so as to become narrow in the vicinity of said plug.

8. The semiconductor device according to claim 1, wherein when a predetermined voltage is applied to said second interconnection, electromigration arises in said second interconnection, thereby establishing connection between said second interconnection and said plug.

9. The semiconductor device according to claim 2, wherein when a predetermined voltage is applied to said second interconnection, electromigration arises in said second interconnection, thereby establishing connection between said second interconnection and said plug.

10. The semiconductor device according to claim 3, wherein when a predetermined voltage is applied to said second interconnection, electromigration arises in said second interconnection, thereby establishing connection between said second interconnection and said plug.

11. The semiconductor device according to claim 4, wherein when a predetermined voltage is applied to said second interconnection, electromigration arises in said second interconnection, thereby establishing connection between said second interconnection and said plug.

12. The semiconductor device according to claim 5, wherein when a predetermined voltage is applied to said second interconnection, electromigration arises in said second interconnection, thereby establishing connection between said second interconnection and said plug.

13. The semiconductor device according to claim 6, wherein when a predetermined voltage is applied to said second interconnection, electromigration arises in said second interconnection, thereby establishing connection between said second interconnection and said plug.

14. The semiconductor device according to claim 7, wherein when a predetermined voltage is applied to said second interconnection, electromigration arises in said second interconnection, thereby establishing connection between said second interconnection and said plug.

15. A semiconductor device having a short circuit or a spare circuit for preventing application of a high voltage to a load circuit, comprising:
a substrate;
a first dielectric film formed on said substrate and having an opening section;
a pad formed in the opening section and having conductivity;
a first interconnection formed on said first dielectric film such that a portion of a bottom of said first interconnection comes into contact with an upper surface of said pad;
a second interconnection formed on said first dielectric film such that a bottom surface of said second interconnection does not come into contact with the upper surface of said pad, said second interconnection being connected to the load circuit, said pad being disposed between said first and second interconnections; and
a second dielectric film having a predetermined void located at a position on said pad, said second dielectric film covering said first and second interconnections.

16. The semiconductor device according to claim 15, wherein said second interconnection is formed so as to become narrow in the vicinity of said pad.

17. The semiconductor device according to claim 15, wherein when a predetermined voltage is applied to said second interconnection, electromigration arises in said second interconnection, thereby establishing connection between said second interconnection and said pad.

18. The semiconductor device according to claim 16, wherein when a predetermined voltage is applied to said second interconnection, electromigration arises in said second interconnection, thereby establishing connection between said second interconnection and said pad.
